(19) United States
(12) Patent Application Publication
(10) Pub. No.: US 2006/0048707 A1
(43) Pub. Date: Mar. 9, 2006

(54) Anti-clogging nozzle for semiconductor processing

(75) Inventors: Lawrence Chung-Lai Lei, Milpitas, CA (US); Siqing Lu, San Jose, CA (US)

Correspondence Address: PATENT COUNSEL;APPLIED MATERIALS, INC., P.O. Box 450A, Santa Clara, CA, 95052, US

(73) Assignee: APPLIED MATERIALS, INC., Santa Clara, CA (US)

(21) Appl. No.: 10/934,213

(22) Filed: Sep. 3, 2004

(51) Int. Cl. C23C 16/00; H01L 21/306

(52) U.S. Cl. 118/715; 156/345.33; 427/248.1

(57) ABSTRACT

Techniques of the present invention are directed to reducing clogging of nozzles. In one embodiment, a method of introducing a gas into a semiconductor processing chamber comprises providing a nozzle having a proximal portion connected to a chamber wall or a gas distribution ring of the semiconductor processing chamber and a distal portion oriented inwardly away from the chamber wall into an interior of the semiconductor processing chamber. The nozzle includes a proximal end coupled with a gas supply, a nozzle opening at a distal end, and a heat shield disposed around at least a portion of the nozzle opening. A nozzle passage extends from the proximal end to the distal end. The method further comprises flowing a gas from the gas supply through the proximal end, the nozzle passage, and the nozzle opening of the nozzle into the interior of the semiconductor processing chamber.

### BACKGROUND OF THE INVENTION

The present invention relates generally to semiconductor manufacturing and, more particularly, to nozzles for delivering gases in semiconductor processing chambers.

Chemical vapor deposition (CVD) is a gas reaction process used in the semiconductor industry to form thin layers or films of desired materials on a substrate. Some high density plasma (HDP) enhanced CVD processes use a reactive chemical gas along with physical ion generation through the use of an RF generated plasma to enhance the film deposition by attraction of the positively charged plasma ions onto a negatively biased substrate surface at angles near the vertical to the surface, or at preferred angles to the surface by directional biasing of the substrate surface. One goal in the fabrication of integrated circuits (ICs) is to form very thin, yet uniform films onto substrates, at a high throughput. Many factors, such as the type and geometry of the power source and geometry, the gas distribution system and related exhaust, substrate heating and cooling, chamber construction, design, and symmetry, composition and temperature control of chamber surfaces, and material build up in the chamber, must be taken into consideration when evaluating a process system as well as a process which is performed by the system.

The clogging of nozzles for delivering process gases into the processing chamber can also affect deposition film properties. Certain nozzles, such as HDP CVD nozzles, are subjected to plasma heating inside the chamber. These nozzles, which are typically long ceramic nozzles with an orifice located at the distal tips, can reach temperatures as high as about 800° C. or higher during the HPD CVD process. The nozzles clean faster than the rest of the chamber components due to its higher temperature (since etchant gases (e.g., fluorine containing gases such as nitrogen trifluoride) used in the clean process work more aggressively to clean at higher temperatures). Other chamber components continue to be cleaned and byproducts, for example, AlF begin to deposit onto the distal nozzle tips. These undesired deposits may cause non-uniformities in the deposition process and may form clogs that eventually restrict nozzle flow.

A current technique to reduce clogging of a nozzle is to mount a ceramic heat shield to the nozzle body. The heat shield allows nozzle temperature to be lowered by absorbing most of the radiation heating onto the shield itself. The heat shield also provides sacrificial surface area for deposits of cleaning process byproducts in lieu of the distal nozzle tip, and thus delays clogging of the nozzle.

Despite the improvement obtainable by using an appropriate heat shield further improvements and/or alternative techniques are desirable for reducing or preventing clogging of nozzles in a semiconductor processing chamber.

### BRIEF SUMMARY OF THE INVENTION

The present invention provides techniques including a method of introducing a gas into a chamber and an apparatus for processing semiconductors. More particularly, embodiments of the present invention are directed to reducing or preventing clogging of nozzles in a semiconductor processing chamber.

According to one embodiment, the present invention provides a semiconductor processing apparatus. The apparatus includes a semiconductor processing chamber and a single piece nozzle. The nozzle body includes a proximal portion connected to a chamber wall of the semiconductor processing chamber and a distal portion oriented inwardly away from the chamber wall into an interior of the semiconductor processing chamber. The nozzle includes a proximal end configured to be coupled with a gas supply, a nozzle opening at a distal end, a nozzle passage extending from the proximal end to the distal end, and a heat shield thermally coupled to the body along length of the body. The heat shield is disposed around at least a portion of the nozzle opening.

According to another embodiment, a gas nozzle adapted for use in a semiconductor processing apparatus is provided. The nozzle body has a proximal portion and a distal portion. The proximal portion is connected to a chamber wall of the semiconductor processing chamber. The nozzle is configured to be coupled with a gas supply at its proximal end. The distal portion is oriented inwardly away from the chamber wall into an interior of the semiconductor processing chamber and has a nozzle opening at a distal end. A nozzle passage extends from the proximal end to the distal end. A heat shield disposed around at least a portion of the nozzle opening. The heat shield is thermally coupled to the nozzle body along length of the nozzle body.

According to yet another embodiment, the present invention provides a method of introducing a gas into a semiconductor processing chamber. The method includes providing a single piece nozzle having a proximal portion connected to a chamber wall or a gas distribution ring of the semiconductor processing chamber and a distal portion oriented inwardly away from the chamber wall into an interior of the semiconductor processing chamber. The nozzle includes a proximal end coupled with a gas supply, a nozzle opening at a distal end, and a heat shield disposed around at least a portion of the nozzle opening. A nozzle passage extends from the proximal end to the distal end. The method further includes flowing a gas from the gas supply through the proximal end, the nozzle passage, and the nozzle opening of the nozzle into the interior of the semiconductor processing chamber.

These and other embodiments of the present invention, as well as its advantages and features, are described in more detail in conjunction with the text below and attached figures.

### BRIEF DESCRIPTION OF THE DRAWINGS

FIG. 1 is a cross-sectional view of a current nozzle for semiconductor processing;

FIGS. 2A and 2B are partial cross-sectional views of a current heat shield for a nozzle;

FIG. 3 is a cross-sectional view of a nozzle according to one embodiment of the present invention;

FIG. 4 is a cross-sectional view of a nozzle according to another embodiment of the invention; and

FIG. 5 is a top plan view schematically illustrating a processing chamber having a plurality of nozzles.

### DETAILED DESCRIPTION OF THE INVENTION

The present invention provides techniques including a method of introducing a gas into a chamber and an apparatus for processing semiconductors. More particularly, embodiments of the present invention are directed to reducing or preventing clogging of nozzles in a semiconductor processing chamber.

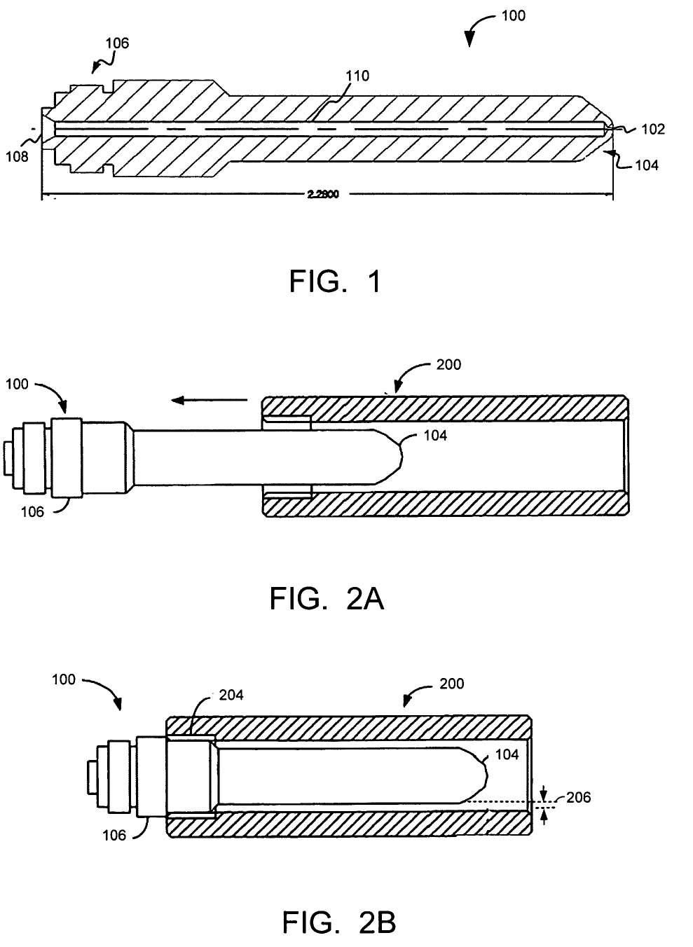

FIG. 1 is cross-sectional view of current nozzle for semiconductor processing. FIG. 1 shows a nozzle 100 having an orifice or nozzle opening 102 disposed at the distal end 104 of the nozzle 100. The nozzle 100 is connected to the chamber wall at a proximal portion 106. Gas is supplied to the nozzle 100 at the proximal end 108. A nozzle passage 110 extends from the proximal end 108 to the distal end 104.

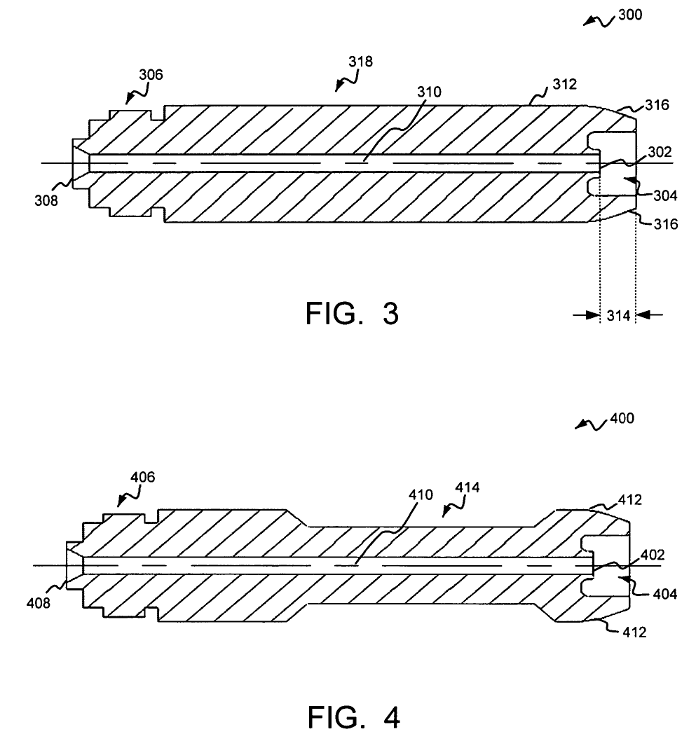

As shown in FIGS. 2A and 2B (similar to FIGS. 3 and 4 from U.S. patent application Publication 2004/0126952), heat shield 200 is configured to be disposed around the entire portion of the nozzle 100 that is exposed in the chamber. The heat shield 200 is typically made of a ceramic material, such as alumina or aluminum oxide, aluminum nitride, silicon carbide, or the like. In specific embodiments, the heat shield 200 and the nozzle 100 are made of the same material, such as aluminum oxide, Al₂O₃. The heat shield 200 as shown is a separate piece that is coupled to the nozzle 100, for example, by a threaded connection 204 or the like. A gap or spacing 206 is disposed between nozzle 100 and heat shield 200.

FIG. 3 is a cross-sectional view of a nozzle according to one embodiment of the present invention. This diagram is merely an example, which should not unduly limit the scope of the claims herein. One of ordinary skill in the art would recognize other variations, modifications, and alternatives. As shown, the present invention provides a nozzle 300 for introducing a gas into a semiconductor processing chamber. Nozzle 300 can be made of any suitable material such as Al₂O₃ and AlN or the like.

Referring to FIG. 3, nozzle 300 has an orifice or nozzle opening 302 disposed at the distal end 304. The nozzle 300 is connected to the chamber wall at a proximal portion 306. Gas is supplied to the nozzle 300 at the proximal end 308. A nozzle passage 310 extends from the proximal end 308 to the distal end 304. In specific examples, the nozzle length may be in the range of about 0.25 to 3.5 inches, or more specifically about 1.70 inches or about 2.28 inches.

Nozzle 300 includes a heat shield 312. Heat shield 312 is thermally coupled to the nozzle body along the length of the nozzle body and is disposed around at least a portion of nozzle opening 302, desirably around the entire nozzle opening 302. The heat shield 312 preferably includes an extension 316 which projects distally of the nozzle opening 302 to recess the nozzle opening 302 by at least 0.125 inches. A length 314 of the extension should be sufficiently large to shield the nozzle opening 302 from the heat in the chamber and to provide sacrificial area for unwanted deposits formed during a chamber clean process. However, the length 314 of the extension should not be so large as to have an adverse effect on the process being performed, such as the uniformity of a layer being formed on the substrate. The length of the extension can be in the range of about 0.125 inches to about 3 inches. In the specific embodiment, a gap or spacing between the extension 316 and nozzle opening 302 is smaller than the thickness of extension 316. It is understood that other configurations, shapes, and thickness profiles of the integrated heat shield 312 may be employed in different embodiments.

As a result of heat shield 312, nozzle opening 302 remains cooler, desirably much cooler than 450° C. during a chamber clean process. In addition, a portion of the unwanted deposits of cleaning byproducts that would normally collect at a nozzle opening, now collect on surfaces of the heat shield. Nozzle 300 also avoids issues relating to differential thermal expansion at the transition from a heat shield to a nozzle and uncertainty with the thermal conductivity between the shield and nozzle. Cracking from thermal shock or differential thermal expansion at the transition from the heat shield to the nozzle is reduced or altogether avoided. Such a nozzle 300 can be conveniently retrofitted into existing CVD chambers.

Nozzle 300 also incorporates an enlarged center body section 318 over current nozzles to raise nozzle body temperature. The associated increase in nozzle body temperature accelerates the heat up of the nozzle and reduces the start up effect on the initial wafer processing. The enlarged nozzle center body section 318 also allows process temperatures to be attained faster. The diameter of the enlarged center body section 318 can be in the range of about 0.28 inches to about 0.75 inches. In a specific example, the diameter of the nozzle center body section is about 0.41 inches.

FIG. 4 is a cross-sectional view of a nozzle according to another embodiment of the invention. Nozzle 400 has an orifice or nozzle opening 402 disposed at the distal end 404. The nozzle 400 is connected to the chamber wall at a proximal portion 406. Gas is supplied to the nozzle 400 at the proximal end 408. A nozzle passage 410 extends from the proximal end 408 to the distal end 404. At the distal portion of nozzle 400, heat shield 412 surrounds nozzle opening 402 to recess nozzle opening by at least 0.125 inches. In addition, the body of nozzle 400 is choked at choke location 414. Body choking helps the nozzle retain temperature at the distal end. It also allows the nozzle to reach process temperatures faster. Retaining temperature seems to promote unwanted deposits since temperatures can remain hot. The primary function of the chocked nozzle is to get to steady state temperature in the shortest time, thereby reducing the first wafer effects. Such a nozzle 400 can be conveniently retrofitted into existing CVD chambers. It is understood that other configurations, shapes, and thickness profiles of the integrated heat shield 412 may be employed in different embodiments.

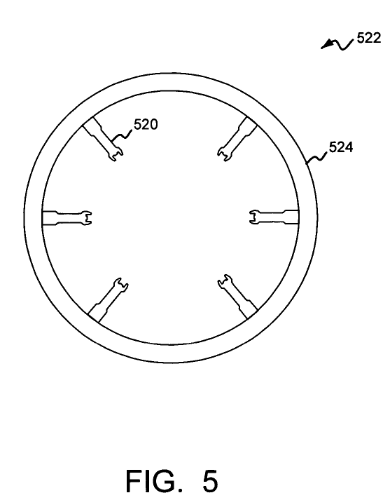

FIG. 5 shows a plurality of nozzles 520 distributed around a chamber 522 and connected to the chamber wall 524. Chamber 522 may have any number of nozzles 520, such as one to about 100. In one specific embodiment, chamber 522 includes thirty-two nozzles. Nozzles 520 include integrated heat shields according to an embodiment of the present invention to prevent or reduce clogging. As discussed above, a root cause of clogging is prevented or inhibited because each heat shield allows the nozzle opening temperature to be lowered than the shield by about 20° C. to about 50° C. and provides sacrificial area for deposits of clean processing byproducts. Therefore, the anti-clogging nozzle can produce improved and consistent deposition on substrates over time.

The above-described arrangements of apparatus and methods are merely illustrative of applications of the principles of this invention and many other embodiments and modifications may be made without departing from the spirit and scope of the invention as defined in the claims. The scope of the invention should, therefore, be determined not with reference to the above description, but instead should be determined with reference to the appended claims along with their full scope of equivalents.

1. A semiconductor processing apparatus comprising:
a semiconductor processing chamber; and
a single piece nozzle, the nozzle having a body, a proximal portion of the body connected to a chamber wall of the semiconductor processing chamber and a distal portion of the body oriented inwardly away from the chamber wall into an interior of the semiconductor processing chamber, the nozzle including a proximal end configured to be coupled with a gas supply, the nozzle including a nozzle opening at a distal end, the nozzle including a nozzle passage extending from the proximal end to the distal end, the nozzle including a heat shield thermally coupled to the body along length of the body, wherein the heat shield is disposed around at least a portion of the nozzle opening.

2. The apparatus of claim 1 wherein a body of the nozzle includes a choke location disposed away from the distal end of the nozzle.

3. The apparatus of claim 2 wherein a diameter of the body is reduced by at least about 30% at the choke location.

4. The apparatus of claim 1 wherein the heat shield extends a length distally beyond the nozzle opening in the range of about 0.125 inches to about 3 inches.

5. The apparatus of claim 1 wherein the heat shield is disposed a length from the nozzle opening in a direction orthogonal to the nozzle passage.

6. The apparatus of claim 1 wherein the nozzle extends from proximal end to distal end in a range of about 0.5 inches to 3.5 inches.

7. The apparatus of claim 1 wherein the nozzle comprises a ceramic material.

8. The apparatus of claim 1 wherein the nozzle comprises at least one of aluminum oxide, aluminum nitride, and silicon carbide.

9. The apparatus of claim 1 wherein the at least one nozzle is 36 nozzles.

10. A gas nozzle adapted for use in a semiconductor processing apparatus, the nozzle comprising:
a nozzle body having a proximal portion and a distal portion, the proximal portion connected to a chamber wall of the semiconductor processing chamber, the distal portion oriented inwardly away from the chamber wall into an interior of the semiconductor processing chamber;
a proximal end configured to be coupled with a gas supply;
a nozzle opening at a distal end;
a nozzle passage extending from the proximal end to the distal end; and
a heat shield disposed around at least a portion of the nozzle opening, the heat shield being thermally coupled to the nozzle body along length of the nozzle body.

11. The apparatus of claim 10 wherein the nozzle body includes a choke location disposed away from the distal end of the nozzle.

12. The apparatus of claim 10 wherein the nozzle comprises at least one of aluminum oxide, aluminum nitride, and silicon carbide.

13. The apparatus of claim 10 wherein the nozzle opening is recessed from a distal end of the heat shield by at least 0.125 inches.

14. The apparatus of claim 10 wherein the nozzle extends about 2.28 inches from proximal end to distal end.

15. The apparatus of claim 10 wherein the nozzle extends about 1.70 inches from proximal end to distal end.

16. A method of introducing a gas into a semiconductor processing chamber, the method comprising:
providing a single piece nozzle having a proximal portion connected to a chamber wall or a gas distribution ring of the semiconductor processing chamber and a distal portion oriented inwardly away from the chamber wall into an interior of the semiconductor processing chamber, the nozzle including a proximal end coupled with a gas supply, the nozzle including a nozzle opening at a distal end, the nozzle including a nozzle passage extending from the proximal end to the distal end, the nozzle including a heat shield disposed around at least a portion of the nozzle opening; and
flowing a gas from the gas supply through the proximal end, the nozzle passage, and the nozzle opening of the nozzle into the interior of the semiconductor processing chamber.

17. The method of claim 16 wherein a body of the nozzle includes a choke location which is spaced away from the distal end.

18. The method of claim 17 wherein a diameter of the body is reduced by at least about 30% at the choke location.

19. The method of claim 16 wherein the heat shield extends distally beyond the nozzle opening.

20. The method of claim 16 wherein the heat shield extends a length distally beyond the nozzle opening in the range of about 0.125 inches to about 3 inches.

21. The method of claim 16 wherein an extension of the heat shield is disposed a length from the nozzle opening in a direction orthogonal to the nozzle passage.

22. The method of claim 16 wherein the heat shield is disposed around the entire nozzle opening.

23. The method of claim 16 further comprising applying energy in the interior of the semiconductor processing chamber to produce a temperature gradient in the nozzle which has a higher temperature in the heat shield than in the distal portion.

24. The method of claim 23 wherein a temperature at the heat shield is higher than a temperature at the distal portion of the nozzle.

25. The method of claim 23 wherein the temperature at the heat shield is higher than the temperature at the distal portion of the nozzle.

26. The method of claim 16 wherein the gas is decomposable to form a deposit of aluminum fluoride in the nozzle opening.

27. The method of claim 26 wherein the gas comprises at least one of fluorine, nitrogen trifluoride, oxygen, silane, dichloro silane, hydrogen, helium, and nitrogen.

28. The method of claim 16 further comprising establishing the semiconductor processing chamber to be at a pressure in a range of about 0.005 Torr to about 10 Torr.
